(19) United States
(12) Patent Application Publication
(10) Pub. No.: US 2026/0066852 A1
(43) Pub. Date: Mar. 5, 2026

(54) Radio Frequency Pre-Drivers with Input Over Voltage Protection

(71) Applicant: Axiro Semiconductor Inc., San Diego, CA (US)

(72) Inventors: Samiran Dasgupta, Bengaluru (IN); HOJUNG JU; Himanshu Khatri, Bengaluru (IN); Chrisben Gladson, Bengaluru (IN)

(73) Assignee: Axiro Semiconductor Inc., San Diego, CA (US)

(21) Appl. No.: 18/822,351

(22) Filed: Sep. 2, 2024

(51) Int. Cl. H03F 1/52; H03F 3/24; H04W 52/52; H04W 88/10

(52) U.S. Cl. CPC H03F 1/52; H03F 3/245; H04W 52/52; H03F 2200/426; H03F 2200/451; H04W 88/10

(57) ABSTRACT

According to an aspect, a pre-driver configured to provide power amplification to a radio frequency (RF) signal received on its input terminal, the pre-driver comprising a power transistor amplifying the RF signal, wherein the RF signal is coupled to the base terminal of the power transistor and power of the RF signal is amplified in the form of a collector current of the power transistor, a bias electronics operative to bias the power transistor in a normal bias for the power amplification and a over voltage protection is coupled to the input terminal is configured to limit the collector current by modifying the bias of the power transistor when the RF signal level increases above a threshold value.

### FIELD OF INVENTION

Embodiments of the present disclosure relate generally to semiconductor devices and circuits and more specifically to a radio frequency pre-drivers with input over voltage protection.

### RELATED ART

Radio Frequency (RF) pre-drivers are generally employed to interface an RF transceiver to power amplifier and drivers that generate a high power signal for transmitting over one or more antennas. Often, the RF transceiver includes a gain block that provide RF signal as output with a certain known or predefined power range. The power amplifier unit are configured to receive certain level (power/voltage/current Level) of input signal. In some operating conditions, the power range at the output of the transceivers is not within the allowable power range at the input of the power amplifier. The RF pre-drivers interface the two blocks matching parameters like power and impedance, and additionally enable the independency and performance optimisation of both transceiver and power amplifier. This is more particularly the case when the gain block, pre-drivers and power amplifiers are adopted to meet different standards or guidelines.

However, in some operating conditions, an increase in the power/voltage/current at the input of the pre-driver may result in corresponding increase in the output power/voltage/current that may damage the power amplifier and/or the pre-driver. Thus, the devices/circuits and the pre-driver needs to be controlled or limited to certain maxima (referred to as over voltage protection). General, technique includes limiting the over voltage (output power) at the output of the pre-driver or at any device.

Some of the known techniques for over voltage protection in the pre-driver are disclosed more fully in the literatures. For example, in one literature titled “A 3.2V Operation Single-Chip Dual Band AlGaAs/GaAs HBT MMIC Power Amplifier with Active Feedback Circuit Technique”, authored by K Yamamoto et al., and published in EEE J Solid State Circuits, Vol. 35, No 8. In this technique, the Tr3 and Tr2 are the output stage and prior stage power transistors. The over voltage detection/protection is done through Trf1 and Trf2 path. They remain off in normal operation and get turned on only in collector overvoltage condition. The trigger point at which Trf1 turns on is decided by the Rfb1 and Rfb2 ratio. Trf2 provides another diode drop and shields parasitic cap of Trf1 from loading the passive Feedback network. Once Trf1 turns on it prevents voltage build up across collector base junction. The main limitation of this technique is that, it only triggered by collector overvoltage and has no means to sense collector current. Hence it cannot detect input over voltage.

Another conventional technique is disclosed in a literature titled “Avalanche Breakdown protection by Adaptive Output Power Control”, authored by A. van Bezooiien et al. and published in 2006 IEEE Radio and Wireless Symposium. In this technique, collector over current is detected through a current sense device and collector overvoltage is sensed by a peak detector. The output from the peak detector and current sensor are summed together and used to generate an adaptive bias using an error amplifier. The main limitation of this technique is that the whole adaptive bias loop is complex and requires current sense, error amplifier, comparator and summer. Further, this technique does not support GaAs HBT process.

Yet another conventional technique is disclosed in a literature titled “An Over-Voltage Protection Circuit for CMOS Power Amplifiers”, authored by Niklas Zimmermann et al., published in 2008 15th IEEE International Conference on Electronics, Circuits and Systems. In this technique, The over voltage is detected between the differential output terminals using an envelope detector, a current steering replica bias that is put in place of the normal replica bias and the envelope detector output is used to control the current steering bias. The limitation is the current steering circuit requires complementary (PMOS) devices not available in GaAs HBT process to dynamically reduce the bias current in the event of over voltage.

Thus, most of the prior art on pre-driver or power amplifier or of any device's overvoltage protection is targeted at output overvoltage and does not address overvoltage at the input. Further, the convention techniques employ complementary (pmos/pnp) devices that are not available in GaAs HBT process (the process in which most state of the art base-station pre-drivers is built). Therefore, there exists a need for over voltage protection technique that overcome at least some of the disadvantages mentioned above and also suitable for suitable for GaAs HBT based pre-drivers.

### SUMMARY

According to an aspect, a pre-driver configured to provide power amplification to a radio frequency (RF) signal received on its input terminal, the pre-driver comprising a power transistor amplifying the RF signal, wherein the RF signal is coupled to the base terminal of the power transistor and power of the RF signal is amplified in the form of a collector current of the power transistor, a bias electronics operative to bias the power transistor in a normal bias for the power amplification and a over voltage protection is coupled to the input terminal is configured to limit the collector current by modifying the bias of the power transistor when the RF signal level increases above a threshold value.

According to another aspect a base station transceiver for transmitting and receiving wireless signal configured to operate for both 4G and 5GNR comprising, a transceiver operative to provide an RF signal for transmission, a gain block providing an amplified RF signal by amplifying the RF signal, wherein the power level of the amplified RF signal is higher in a calibration and startup phases, a pre-driver coupling the amplified RF signal to a power amplifier, the pre-driver employing GaAs HBT process comprises a power transistor amplifying the RF signal, wherein the RF signal is coupled to the base terminal of the power transistor and power of the RF signal is amplified in the form of a collector current of the power transistor, a bias electronics operative to bias the power transistor in a normal bias for the power amplification and a over voltage protection is coupled to the input terminal is configured to limit the collector current by modifying the bias of the power transistor when the RF signal level increases above a threshold value.

According to another aspect, a method to provide power amplification to a radio frequency (RF) signal comprising, biasing an amplifier to operate at a first operating condition to amplify the RF signal received on its input terminal, detecting an overvoltage at the input of the amplifier, wherein the overvoltage representing a voltage value of the RF signal greater than a threshold and biasing the amplifier to a second operating condition when the said detecting results in the overvoltage, wherein, the amplifier does not amplify the RF signal in the second operating condition.

Several aspects are described below, with reference to diagrams. It should be understood that numerous specific details, relationships, and methods are set forth to provide a full understanding of the present disclosure. One who skilled in the relevant art, however, will readily recognize that the present disclosure may be practiced without one or more of the specific details, or with other methods, etc. In other instances, well-known structures or operations are not shown in detail to avoid obscuring the features of the present disclosure.

### BRIEF DESCRIPTION OF DRAWINGS

FIG. 1 is a block diagram illustrating the pre-driver in an embodiment.

FIG. 2 is a circuit diagram illustrating the manner in which the pre-driver may be implemented in an embodiment.

FIG. 3A and FIG. 3B depict the over voltage protection 220 implemented in an embodiment and an alternative embodiment respectively.

FIG. 4 illustrates another embodiment of the pre-driver with over voltage protection employed at the input.

FIG. 5 is a set of graph illustrating the operation of overvoltage protection in an embodiment.

FIG. 6 is a block diagram illustrating deployment of the pre-drier in an example system.

FIG. 7 is a block diagram illustrating the manner in which the overvoltage protection may be provided through altering the bias condition in an embodiment.

### DETAILED DESCRIPTION OF THE PREFERRED EXAMPLES

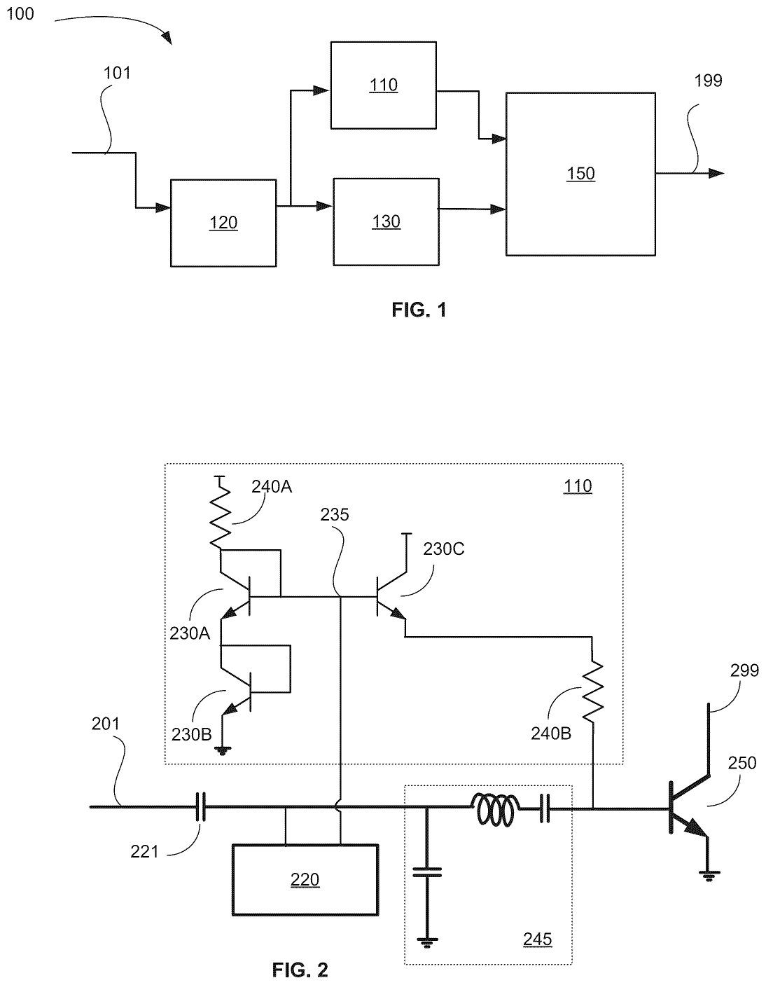

FIG. 1 is a block diagram illustrating the pre-driver in an embodiment. The pre-driver 100 is shown comprising power transistor 150, bias electronics 110, matching electronics 130, over voltage protection 120. In that, the power transistor 150 provides the power transition to the RF signal received on path 101. The RF signal that is modified in power (one of voltage and current or both) is provided on the path 199. The bias electronics 110 provides operating conditions to the power transistors 150. The bias electronics 110 provides desired bias voltage/current to the power transistor 150 such that the power transistor 150 translates the RF signal at the input to corresponding RF signal at the output with enhanced voltage/current/power. The bias electronics 110 is coupled to a voltage source (often referred Vs or Vcc) to provide bias voltage/current to the power transistor 150. The matching electronics 130 provides frequency and impendence matching interface to RF input signal with the power transistor 150. The matching electronics couples the RF signal with minimal attenuation to the power transistor 150 for the frequency (bandwidth) of the RF signal. The over voltage protection 120 is coupled to the input terminal of the power amplifier and it detects signal level (for example, voltage) of the input RF signal that may cause overvoltage at the out of the power transistor 150 and controls/limits the output power (current/voltage) of the power transistor 150 within a threshold value. As a result, the overvoltage protection is provided at the input of the power amplifier to control the output power. The overvoltage protection operates even for GaAs HBT based pre-drivers.

FIG. 2 is a circuit diagram illustrating the manner in which the pre-driver 200 may be implemented in an embodiment. The circuit diagram is shown comprising power transistor 250 that operate as main transistor providing the power amplification in the pre-driver 200. The transistors 230A, 230B and 230C together with the resistors 240A and 240B form the bias electronics 110 providing the desired bias voltage and current to the power transistor 250. In that, the transistor 230C provides the required base current to the power transistor 250. The collector current of the transistor 230C determines the base current of the power transistor 250. The potential (direct current (DC) voltage level) at the node 235 determines the collector current of the transistor 230. The resistance value of the resistors 240A and 240B are set to provide the desired bias potential at the point 235 through the transistors 230A and 230B.

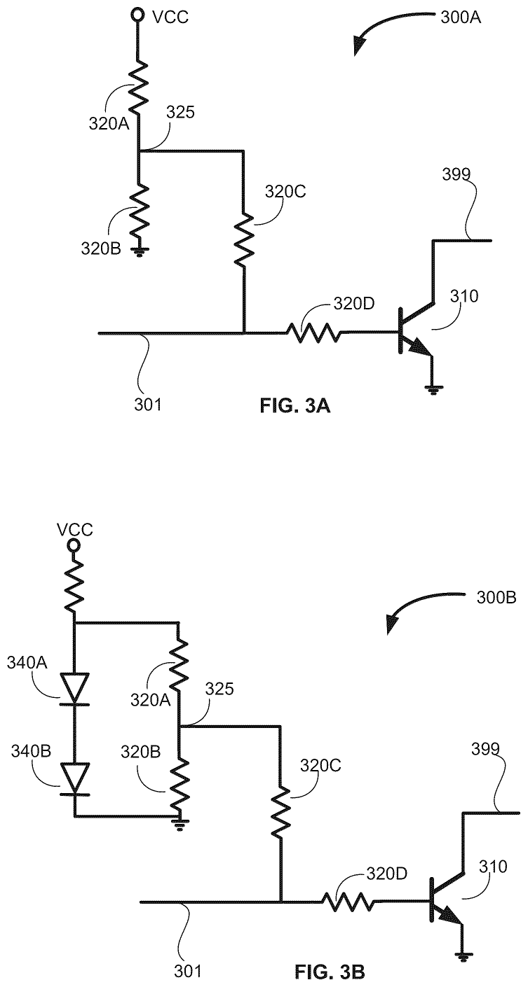

The over voltage protection 220 is shown coupled between the input terminal 201 and the point 235. The overvoltage protection 220 is configured to reduce the potential at point 235 when the RF signal value at the input terminal 201 exceeds a threshold value. When the potential at point 235 is reduced, the collector current of the transistor 230C reduces, thereby reducing the base terminal current (potential) of the power transistor 250 to a value that is bellow the required bias potential/current of the power transistor 250. As a result the collector current of the power transistor 250 is reduced when the input RF signal level crosses the pre set threshold. Thus, the pre-driver over voltage protection is provided at the output terminal 299 though the input terminal 201. The over voltage protection 220 may be coupled to the RF signal through a capacitor 221. The matching circuit 245 may comprise inductor and capacitance network (as shown with standard notations) providing impedance matching to the power transistor 250. The manner in which the over voltage protection 220 may be implemented in an embodiment is depicted in the FIG. 3A and an alternative embodiment is illustrated in the FIG. 3B.

In the FIG. 3A, the over voltage protection 300A is shown comprising transistor 310 and resistors 320A through 320D. The transistor 310 is biased through 320A-320D. In that, the resistors 320A and 320B operate as voltage divider to provide bias potential to the base terminal of the transistor 310. The resistors 320C and 320D provide the bias base current to the transistor 310. In operation, the over voltage protection 300A has two terminals 301 and 399, one terminal 301 is connected to the RF input, other terminal 399 connected to the biasing node 235. The input RF signal is capacitively coupled to the input terminal 301. The transistor 310 remains off in normal operation and only turns on once RF input overvoltage is detected. The input threshold at which the transistor 310 activates is controlled by the bias voltage Vbprot at point 325. The Vbprot is set to a value that is slightly less than base potential of power transistor 250, such that transistor 310 does not turn on during normal operation (that is as long as the RF input signal level is less than the threshold). Once RF input signal crosses the threshold the transistor 310 turns on and pulls down node 235 of the FIG. 2 that results in restricting the collector current of the power transistor 250. In FIG. 3B, additional diodes 340A and 340B are connected in parallel to the resistors 320A and 320B, the diodes 340A and 340B provides thermal stability to the potential Vbprot at point 325.

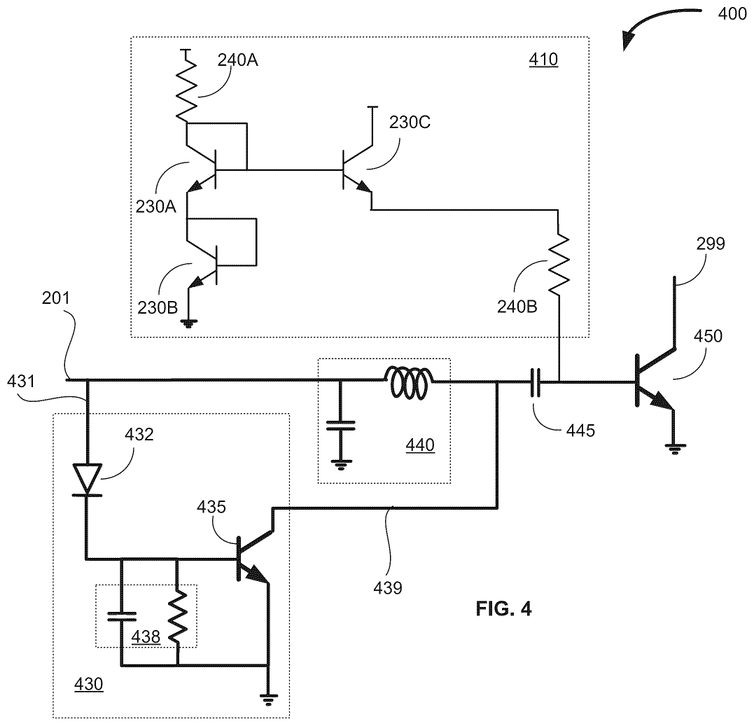

FIG. 4 illustrates another embodiment of the pre-driver with over voltage protection employed at the input. The pre-driver 400 is shown with power amplifier 450, bias electronics 410, matching network 440, and the over voltage protection 430. The power amplifier 450 is biased through the bias electronics 410. The over voltage protection 430 is shown comprising diode 432, transistor 435 and an RC network 438. The power amplifier 450 (a power transistor), bias electronics 410, and matching network 440 are operative similar to the power transistor 150, bias electronics 110, and matching electronics 130 described in the above sections with reference to FIG. 1 and FIG. 2. The over voltage protection 430 is placed at the input before the matching network. It has two terminals 431 and 439 with terminal 431 connected to receive the RF input signal (as in terminal 201 of FIG. 2), other terminal 439 is connected to the base terminal of the power amplifier 450 through a decoupling capacitor 445. The transistor 435 is off in normal operation and only turns on once RF input signal crosses a threshold. In that, when the input RF signal rises one diode-drop (corresponding to diode 432) above the turn on voltage of the transistor 435, the transistor 435 turns ON. Thus, the collector of the transistor 435 pulls down the base of power transistor 450 resulting in arresting any over voltage at the output of the pre-driver when the input RF signal value crosses a threshold value.

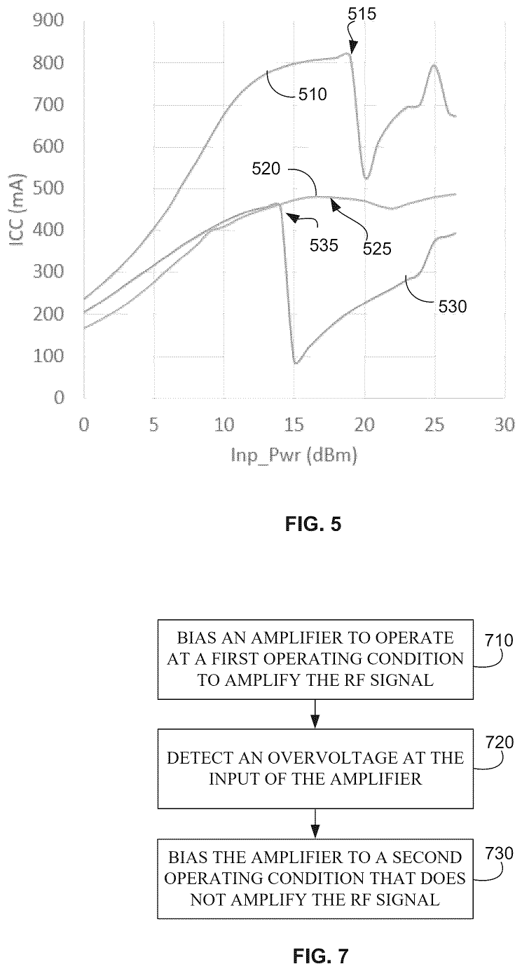

FIG. 5 is a set of graph illustrating the operation of overvoltage protection in an embodiment. With X-axis representing power of the RF input signal at the terminal 201 and Y-axis representing the collector current of the power transistor (say 250/450), the graphs 510, 520 and 530 respectively represent example operation and performance of the overvoltage protection 220 at frequencies 650 MHz, 850 MHz, and 450 MHz. As shown there the pull back point 515, 525 and 535 represents the activation of the overvoltage protection that is configured to limit the collector current of the power transistor to 1 Ampere. The behaviour (different peak current) is shown as frequency dependent as the sense point of the over voltage protection circuit is at the input pad that is before the matching network and the matching network drop is frequency dependent. As shown, for all cases of frequency, the collector current of the power transistor is limited below 1000 mA as desired.

Physically the overvoltage protection circuit is at the input of the LNA/pre-amplifier, unlike prior methods which require the protection to be placed at the output i.e. the collector of the power transistor. Advantages over prior art are that the instant pre-driver it is able to protect input overvoltage up to 26 dBm, uses only resistors and a single HBT, thus compatible with GaAs HBT process, does not use any control loop, comparator, error amplifier or digital logic, does not involve any feedback mechanism and hence does not compromise stability and does not interfere with normal mode of operation.

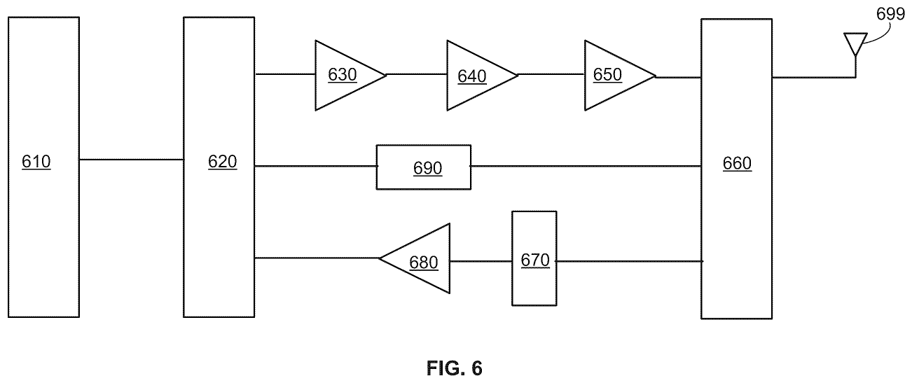

FIG. 6 is a block diagram illustrating deployment of the pre-drier in an example system. The example system is a base-station transceiver chain. In that the block 610 is a signal and data processing block operative to perform desired data processing in accordance application for which the example system is implemented and may comply with the known standards like 4G/5GNR. The block 610 may be implemented as a ASIC (application specific Integrated circuit) or as an IP in an SoC (system on chip).

Similarly, the block 620 is a transceiver configured to perform the operation of transmitting the data received from the block 610 over the antenna 699 meeting the communication standards. In one embodiment, the block 620 is a sub-8 Ghz transceiver that performs suitable modulation and signal conditioning for transmission. The signal received from the block 620 is provided to the gain block 630 for first level of amplification. The power amplifier 650 provides the final power gain to the signal for transmission over the antenna 699. The block 660 is a matching network that may comprise filter and circulators for effectively coupling the power amplified signal to the antenna 699.

The pre-driver 640 interface the gain block 630 to the power amplifier 650. In certain embodiment, the pre-driver 640 and the Gain Block 630 may be implemented as two different chips and may be from two different sources. That is, the blocks 630, 640 and 650 may be developed and deployed independently for optimal performance or with legacy/existing devices. in certain conditions like as in 5GNR applications, depending on the configuration of the OEM (Original Equipment manufacturer) the Gain Block 630 output i.e. the input to the pre-driver 640 may be as high as 27 dBm during calibration or start up phase; such high signal would damage the conventional pre-driver input stage. In other conditions, say for example in older generation (3 g/4GNR) pre-drivers, the required input overvoltage tolerance is set to max 16 dBm. However, this has been increased to 27 dBm for certain 5GNR applications. Thus, the present an input overvoltage protection circuit 220 in the pre-driver 640 is suitable for GaAs HBT based pre-drivers and may tolerate input overvoltage up to 27 dBm and at the same time allow linear pre-driver operation up to 29 dBm OPIdB. The blocks 670 and 680 are representing the switch and low noise amplifier to aid the test driven development environment of the system. The block 690 representing the DPD (digital pre distortion) block as is well known in the art.

FIG. 7 is a block diagram illustrating the manner in which the overvoltage protection may be provided through altering the bias condition in an example system. In block 710, the system biases an amplifier to operate at a first operating condition to amplify the RF signal received on its input terminal. In the block 720, the system detects an overvoltage at the input of the amplifier, wherein the overvoltage representing a voltage value of the RF signals greater than a threshold. In the block 730, the system biases the amplifier to a second operating condition that does not amplify the RF signal, when the said detecting in step 720 is positive (that is the overvoltage being detected).

While various examples of the present disclosure have been described above, it should be understood that they have been presented by way of example, and not a limitation. Thus, the breadth and scope of the present disclosure should not be limited by any of the above described examples, but should be defined in accordance with the following claims and their equivalents.

What is claimed is,

1. A pre-driver configured to provide power amplification to a radio frequency (RF) signal received on its input terminal, the pre-driver comprising:
a power transistor amplifying the RF signal, wherein the RF signal is coupled to the base terminal of the power transistor and power of the RF signal is amplified in the form of a collector current of the power transistor;
a bias electronics operative to bias the power transistor in a normal bias for the power amplification; and
a over voltage protection is coupled to the input terminal is configured to limit the collector current by modifying the bias of the power transistor when the RF signal level increases above a threshold value.

2. The pre-driver of claim 1, wherein the overvoltage protection comprises a control transistor that turn on when the RF signal level increases above a threshold value and remain off otherwise.

3. The pre-driver of claim 2, wherein the collector terminal of the transistor is coupled to the bias electronics to alter the bias of the power transistor when the control transistor is turned on.

4. The pre-driver of claim 2, wherein the collector terminal of the control transistor is coupled to the base terminal of the power transistor to pull the potential of the base terminal of the power transistor to a value less than the normal bias potential when the control transistor is turned on.

5. The pre-driver of claim 3, wherein the bias electronics comprising a first transistor that is configured to provide the normal bias potential at the base terminal of the power transistor and the control transistor is coupled to the base terminal of the first transistor.

6. The pre-driver of claim 4, wherein the control transistor base terminal is coupled to the RF signal through a diode.

7. A base station transceiver for transmitting and receiving wireless signal configured to operate for both 4G and 5GNR comprising:
a transceiver operative to provide an RF signal for transmission;
a gain block providing an amplified RF signal by amplifying the RF signal, wherein the power level of the amplified RF signal is higher in a calibration and startup phases;
a pre-driver coupling the amplified RF signal to a power amplifier, the pre-driver employing GaAs HBT process comprises a power transistor amplifying the RF signal, wherein the RF signal is coupled to the base terminal of the power transistor and power of the RF signal is amplified in the form of a collector current of the power transistor;
a bias electronics operative to bias the power transistor in a normal bias for the power amplification; and
a over voltage protection is coupled to the input terminal is configured to limit the collector current by modifying the bias of the power transistor when the RF signal level increases above a threshold value.

8. The base station transceiver of claim 7, wherein the overvoltage protection comprises a control transistor that turns on when the RF signal level increases above a threshold value and remain off otherwise.

9. The base station transceiver of claim 8, wherein the collector terminal of the transistor is coupled to the bias electronics to alter the bias of the power transistor when the control transistor is turned on.

10. The base station transceiver of claim 8, wherein the collector terminal of the control transistor is coupled to the base terminal of the power transistor to pull the potential of the base terminal of the power transistor to a value less than the normal bias potential when the control transistor is turned on.

11. A method to provide power amplification to a radio frequency (RF) signal comprising:
biasing an amplifier to operate at a first operating condition to amplify the RF signal received on its input terminal;
detecting an overvoltage at the input of the amplifier, wherein the overvoltage representing a voltage value of the RF signal greater than a threshold; and
biasing the amplifier to a second operating condition when the said detecting results in the overvoltage,
wherein, the amplifier does not amplify the RF signal in the second operating condition.

12. The method of claim 11, further comprising reverting to the first operating condition when the RF signal value recedes below the threshold.

13. The method of claim 12, wherein the amplifier is a transistor configured with the base terminal receiving the RF signal and its collector terminal providing the amplified output RF signal.

14. The method of claim 13, further comprising limiting the collector current by modifying the bias of the transistor when the RF signal level increases above a threshold value.
